(19) United States
(12) Patent Application Publication
(10) Pub. No.: US 2014/0220731 A1
(43) Pub. Date: Aug. 7, 2014

(54) BINDER-FREE PROCESS FOR PREPARING PHOTOANODE OF FLEXIBLE DYE-SENSITIZED SOLAR CELL

(71) Applicant: NATIONAL CHENG KUNG UNIVERSITY, Tainan City (TW)

(72) Inventors: JYH-MING TING, Tainan City (TW); LI-CHIEH CHEN, Tainan City (TW); Yuh-Lang Lee, Tainan City (TW); Min-Hsiung Hon, Tainan City (TW)

(73) Assignee: NATIONAL CHENG KUNG UNIVERSITY, Tainan City (TW)

(21) Appl. No.: 13/760,470

(22) Filed: Feb. 6, 2013

(51) Int. Cl. H01L 31/18

(52) U.S. Cl. CPC H01L 31/1884
USPC 438/98

(57) ABSTRACT

The present invention provides a binder-free process for preparing a photoanode of flexible dye-sensitized solar cell, comprising: (a) preparing a TiO₂ suspension fluid comprising TiO₂, acetylacetone and anhydrous ethanol; (b) preparing a charge solution comprising iodine, ketone and deionized water; (c) mixing said TiO₂ suspension fluid and said charge solution to obtain an electrophoresis suspension; (d) soaking a substrate and a cathode into the electrophoresis suspension and proceeding electrophoresis to obtain an TiO₂ deposited substrate, in which said substrate and said cathode are flexible; (e) heating the TiO₂ deposited substrate; and (f) compressing the heated TiO₂ substrate to obtain the photoanode.

### BACKGROUND OF THE INVENTION

1. Field of the Invention

The present invention relates to a binder-free process for preparing a photoanode of flexible dye-sensitized solar cell, in which the photoanode is obtained by electrophoretically depositing a TiO₂ film on a flexible substrate.

2. Description of the Related Art

In recent years, both academia and industry have paid great attention to dye-sensitized solar cells (DSCs) due to their low cost production, simple processing, and relatively high efficiency up to 11% (Chen et al., ACS Nano, 2009, 3(10), 3103-3109; Wang, et al., Nat. Mater., 2003, 2(6), 402-407; Gratzel, J. Photochem. Photobiol., C, 2003, 4(2), 145-153). The electrodes used in typical DSCs are supported on indium-tin-oxide (ITO) coated glass substrates, making the cells rigid. However, considering the weight reduction and the growing number of flexible electronic devices, DSCs having plastic substrates such as ITO-coated poly(ethylene terephthalate) (PET) and ITO-coated poly(ethylene naphthalate) (PEN) receive increasing interest (Gutierrez-Tauste, et al., J. Photochem. Photobiol., A, 2005, 175(2-3), 165-171; Shin, et al., ACS Appl. Mater. Interfaces, 2010, 2(1), 288-291; Lee, et al., J. Mater. Chem., 2009, 19(28), 5009-5015). An added advantage is that the use of these substrates allows the fabrication of flexible DSCs (FDSCs) based on large scale roll-to-roll processes. Due to the use of plastics, typical photoanode synthesis temperatures cannot exceed 150° C. As a result, one of the challenges facing the development of such FDSCs is to obtain photoanodes having well-connected TiO₂ nanoparticles and good adhesion to the substrates. In conventional rigid DSCs, the photoanodes are synthesized at high temperatures near 450° C. At these temperatures, not only organic additives can be effectively removed but also the desired necking among TiO₂ nanoparticles can be achieved. On the other hand, for plastic substrate FDSCs, the necking cannot occur and organic additives are likely to remain in the photoanodes. Many low temperature synthesis processes have therefore been investigated to enhance the contacts among TiO₂ nanoparticles and the adhesion between photoanode and substrate. Yamaguchi et al. pioneered a mechanical compression method for the fabrication of plastic substrate FDSCs (Yamaguchi, et al., Sol. Energy Mater. Sol. Cells, 2010, 94(5), 812-816). In another approach, glass substrates were pre-treated using a TiCl₄ aqueous solution to enhance the adhesion between the TiO₂ layer and the glass substrate, and the deposited TiO₂ layer was also treated using the same solution to improve the binding among TiO₂ nanoparticles (Sommeling, et al., J. Phys. Chem. B, 2006, 110(39), 19191-19197; Vesce, et al., J. Non-Cryst. Solids, 2010, 356(37-40), 1958-1961). Both treatments were performed at 70° C.

Such TiCl₄ treatment, however, can only be used for glass substrates not plastic substrates due to the vulnerable chemical resistance of the plastic to TiCl₄ solution. A chemical sintering process was studied to allow chemical bonding among the TiO₂ nanoparticles due to the addition of an acid or a base agent (Weerasinghe, et al., J. Photochem. Photobiol., A, 2010, 213(1), 30-36). This study also used glass as the substrate.

The approach used here involves electrophoretic deposition (EPD). However, so far there are very few reports investigating the use of EPD to fabricate TiO₂ photoanodes on different rigid or flexible substrates. Miyasaka et al. used an EPD technique followed by 150° C. annealing for the fabrication of photoanodes on ITO-PET substrates (Miyasaka, et al., J. Electrochem. Soc., 2004, 151(11), A1767-A1773). However, the counter electrode was made on a SnO₂ glass substrate, making the cell rigid. The TiO₂ used was a mixture of commercial F-5 (average particle size=20 nm) and G-2 (average particle size=500 nm) powders, and the weight ratio of F-5:G-2 was 3. In order to obtain a high current density (9.0 mA/cm²) and therefore a high cell efficiency (4.1%), repeated cycles of EPD and wet chemical binding treatments were used. Without the cycles, the current density and cell efficiency were low and poor. The cycled processes, giving a photoanode thickness of 10 μm, were also found to give the needed adhesion between the photoanode and the ITO-PET substrate. It is noted that a very high electric field of 1200 V/cm was used. Another work also involved the use of rigid glass substrates. Photoanodes consisting of either commercial P25 (average particle size 22 nm) or P-90 (average particle size 14 nm) TiO₂ powders were fabricated on FTO glass substrates using an EPD technique followed by compression and/or annealing at 150 or 500° C. (Grins, et al., J. Photochem. Photobiol., A, 2008, 198(1), 52-59). The focus was on improving the high temperature sintered photoanodes for use in rigid cells. However, an extra step of applying non-polar volatile organic liquids to fill the pores of EPD TiO₂ coatings was used before the compression. Also, multiple EPD coatings were needed to obtain a final thickness near 25 μm.

TiO₂ photoanodes were prepared on flexible Ti-metal sheets using EPD, at a high electric field of 48 V/cm, followed by chemical treatment with tetra-n-butyl titanate (TBT) and sintering at 450° C. (Tan, et al., Electrochim. Acta, 2009, 54(19), 4467-4472). The photoanode consists of a transparent layer (P25 powders) and a light-scattering layer (100 nm TiO₂ powders), with the weight ratio of the transparent to the lightscattering layer being 12.5. A conversion efficiency of 6.33% was obtained as a result of the extra TBT treatment (photoanode thickness=11 μm). Such a treatment is needed for the formation of secondary anatase TiO₂, interconnecting the primary TiO₂ particles and improving the adhesion of the photoanode to the substrate. A recent study reports the preparation of TiO₂ photoanodes (P25) on an ITO-PEN substrate using EPD followed by mechanical compression (Chen, et al., J. Power Sources, 2010, 195(18), 6225-6231). A very high electric field of 300 V/cm was used and the effect of compression pressure was addressed. The resulting cell exhibited a conversion efficiency up to 4.37% at a photoanode thickness of 10.9 μm.

From above, it is known that the electrophoresis system applied for DSCs is a binder-free system, which avoids high temperature sintering. This is advantageous for flexible materials, and becomes a hot issue.

### SUMMARY OF THE INVENTION

Accordingly, the present invention relates a novel binder-free electrophoretic deposition (EPD) process for preparing a photoanode of all-plastic flexible dye-sensitized solar cell (FDSC), and the all-plastic FDSC manufactured by the process. Furthermore, a non-evaporable gel-electrolyte is used in the FDSCs of the present invention, which prolongs the lifespan of the FDSCs of the present invention.

One object of the present invention is to provide a binder-free EPD process for preparing a photoanode of FDSCs, which is capable of obtaining a photoanode with an electrophoretically deposited TiO₂ film.

Another object of the present invention is to provide a flexible dye-sensitized solar cell comprising a photoanode prepared by the binder-free EPD process, which has enhanced cell efficiency.

To achieve these objects, the present invention provides a binder-free EPD process for preparing a photoanode of flexible dye-sensitized solar cell, comprising:
(a) preparing a TiO₂ suspension fluid comprising TiO₂, acetylacetone and anhydrous ethanol;
(b) preparing a charge solution comprising iodine, ketone and deionized water;
(c) mixing said TiO₂ suspension fluid and said charge solution to obtain an electrophoresis suspension;
(d) soaking a substrate and a cathode into the electrophoresis suspension and proceeding electrophoresis to obtain an TiO₂ deposited substrate, in which said substrate and said cathode are flexible;
(e) heating the TiO₂ deposited substrate; and
(f) compressing the heated TiO₂ substrate to obtain the photoanode.

In a preferred embodiment of the EPD process, said TiO₂ is selected from P25, ST41 or combinations thereof; more preferably, said TiO₂ is selected from combinations of P25 and ST41.

In a preferred embodiment of the EPD process, said P25 and ST41 are combined with a ratio of 0.5˜9:1; more preferably, combined with a ratio of 1.9˜6:1; and even more preferably, combined with a ratio of 3:1.

In a preferred embodiment of the EPD process, said TiO₂, acetylacetone and anhydrous ethanol are combined with a ratio of 3 g˜4 g:1.2 mL˜2 mL:1 L˜1.2 L; more preferably, combined with a ratio of 3 g:2 mL:1 L.

In a preferred embodiment of the EPD process, said iodine, ketone and deionized water of step (b) are combined with a ratio of 0.067 g˜0.075 g:10 mL˜15 mL:5 mL˜10 mL; more preferably, combined with a ratio of 0.067 g:10 mL:5 mL.

In a preferred embodiment of the EPD process, said substrate is a flexible substrate; more preferably, selected from ITO-PEN, ITO-PET, titanium or stainless steel substrate; even more preferably, selected from an ITO-PEN, or ITO-PET substrate.

In a preferred embodiment of the EPD process, said substrate and the cathode are arranged with a distance of 0.5 cm˜1.2 cm in step (d); more preferably, with a distance of 1 cm in step (d).

In a preferred embodiment of the EPD process, said deposited TiO₂ substrate is heated at 100-140° C.; more preferably, heated at 140° C.

In a preferred embodiment of the EPD process, said deposited TiO₂ substrate is compressed at 20 kg/cm²˜50 kg/cm² in step (f); more preferably, compressed at 50 kg/cm² in step (f).

The present invention also provides a flexible dye-sensitized solar cell, comprising: (1) an anode, which is a photoelectrode comprising a substrate covered with an electrophoretically deposited TiO₂ film; (2) a cathode; and (3) a gel-electrolyte.

In a preferred embodiment of the flexible dye-sensitized solar cell of the present invention, said TiO₂ is selected from P25, ST41 or combinations thereof; more preferably, said TiO₂ is selected from combinations of P25 and ST41.

In a preferred embodiment of the flexible dye-sensitized solar cell of the present invention, said P25 and ST41 are combined with a ratio of 0.5˜9:1; more preferably, combined with a ratio of 1.9˜6:1; and even more preferably, combined with a ratio of 3:1.

In a preferred embodiment of the flexible dye-sensitized solar cell of the present invention, said substrate is a flexible substrate; more preferably, selected from ITO-PEN, ITO-PET, titanium or stainless steel substrate; even more preferably, selected from an ITO-PEN, or ITO-PET substrate.

In a preferred embodiment of the flexible dye-sensitized solar cell of the present invention, said cathode is a titanium-coated flexible substrate; more preferably, said cathode is a titanium-coated ITO-PEN substrate.

In a preferred embodiment of the flexible dye-sensitized solar cell of the present invention, said gel-electrolyte is composed of liquid electrolyte and PAN-VA; more preferably, said gel-electrolyte comprises 7% PAN-VA; and most preferably, said liquid electrolyte consists of 0.1M LiI, 0.05M I₂, 0.5M TBP, 0.6M DMPII and 7 wt % PAN-VA in MPN.

In a preferred embodiment of the flexible dye-sensitized solar cell of the present invention, said flexible dye-sensitized solar cell comprises a photoanode prepared by the binder-free EPD process of the present invention.

In the present invention, low voltage (≦25 V) or electric field (≦25 V/cm) is used in the EPD process. No binder is applied during the EPD process of the present invention, and high temperature heat treatment is not needed for removing the binder. This is advantageous for the fabrication of all-plastic FDSCs because the temperature limit of plastic materials. In addition, no chemical treatment was applied during the fabrication of the photoanodes of the present invention. Therefore, the present invention provides an easy and fast EPD process for preparing a photoanode with an electrophoretically deposited TiO₂ film, and the flexible dye-sensitized solar cell of the invention has enhanced cell efficiency.

### BRIEF DESCRIPTION OF THE DRAWINGS

FIG. 1 shows the illustrative diagram of (a) P25 film and (b) PS (P25+ST41) film.

FIG. 2 shows the SEM images of (a) P25, (b) ST41 and (c) PS deposited on ITO-PEN substrate.

FIG. 3 shows the relationship of electric field and thickness of (a) P25 films and (b) PS films.

FIG. 4 shows the relationship of BET surface area, dye loading per volume and thickness of (a) P25 films and (b) PS films.

FIG. 5 shows (a) IPCE spectra and (b) normalized IPCE spectra of Cells G, I, O and Q.

### DETAILED DESCRIPTION OF THE PREFERRED EMBODIMENTS

All scientific terms hereinafter are given their ordinary meaning in the usage of the field of the invention, unless the text of the patent makes clear that a term is used with a special meaning.

### Preparation of Electrophoretic Suspension

First, a TiO₂ suspension fluid containing TiO₂ powder, absolute anhydrous ethanol (J. T. Baker), and acetylacetone (C₅H₈O₂, Fluka) was prepared. The solid to liquid ratio of the TiO₂ suspension fluid was 3 g/L. The volume ratio of acetylacetone to anhydrous ethanol is less than 0.2%. The TiO₂ suspension fluid was stirred for one day to ensure homogeneity.

Two TiO₂ powders were used in the present invention, namely, P25 (20 nm in diameter, 80% anatase: 20% rutile) (Degussa, Germany) and ST41 (160 nm in diameter, 100% anatase) (Ishihara Sangyo, Japan). The mixture of P25 and ST41 (PS) was also used, in which the weight ratio of P25 to ST41 was 3:1.

A solution containing iodine (I₂, Aldrich), ketone, and deionized water was used as the charge solution, in which iodine:ketone:deionized water=0.067 g:10 mL:5 mL. No alcohol is comprised in the charge solution of the present invention. Then the charge solution and the TiO₂ suspension fluid were mixed with a ratio of 1 mL:10˜15 mL to obtain an electrophoretic suspension.

### Preparation of Photoanode

Binder-free electrophoretic deposition (EPD) and mechanical compression were employed to fabricate the photoanode of the present invention.

A cathode (i.e. counter electrode) was prepared separately. A vacuum platinum coater (JEOL 1600) was used to coat Pt on an ITO-PEN substrate (Peccell, Japan) with a current of 20 mA for 200 seconds. The cathode, an ITO-PEN substrate and the electrophoretic suspension were subjected to EPD bath, in which the distance between the cathode and the ITO-PEN substrate was 1 cm. During EPD, the voltage was applied from 5 to 25V for 2 or 4 min to deposit TiO₂ powders onto the ITO-PEN substrate. After that, the deposited TiO₂ substrate was subjected to heat treatment at 140° C. to remove excess residuals. Then the heat treated substrate was mechanically compressed at 50 kg/cm² (=MPa) by a thermocompressor to obtain a photoanode for FDSCs.

### Preparation of Flexible Dye-Sensitized Solar Cell

Flexible dye-sensitized solar cell of the present invention was assembled by using the photoanode prepared as above, in which N719 (cis-bis-(Isothiocyanato)-bis-(2,2′bipyridyl-4,4′dicarboxylato) ruthenium (II) bis-tetrabutyl-ammonium) (Solaronix) was used as the dye comprised in the cell. 0.05 g of solid N719 was added into 100 mL of ethanol, and stirred and sonicated to obtain a N719 solution having a concentration of 5×10⁻⁴ M, then the solution was aliquoted and stored in the dark.

The obtained photoelectrode was soaked into the N719 solution for about one day, so the time was sufficient for dye to be loaded on the surface of the deposited TiO₂ film of the present invention. After soaking, the photoelectrode was removed and soaked into ethanol for about 10 minutes in order to remove the extra dye aggregates. After that, the photoelectrode was removed and dried, and ready for cell assembly.

A solution of 0.1M LiI (Aldrich, 99.99%), 0.05M I₂ (Aldrich, 99.999%), 0.5M TBP (4-tert-butylpyridine) (Aldrich, 99%) and 0.6M DMPII (1,2-dimethyl-3-n-propylimidazolium iodide) (Solaronix) in MPN (3-methoxy-propionitrile) (Alfa Aesar, 99%) was prepared as a liquid electrolyte. Then 7% PAN-VA (polyacrylonitrile-co-vinyl acetate polymer) was added, heated at 120° C. and stirred at 50 rpm for 5-7 minutes to obtain the non-volatile gel-electrolyte for the FDSC of the present invention. In addition, PAN would promote the dissociation of LiI, leading to a high Li⁺ ion concentration in the gel-electrolyte, thereby resulting in a positive shift of the TiO₂ bandgap.

At last, the dye-sensitized solar cell was assembled. A spacer with pores (Surlyn) and having a thickness of 60 μm and a width of 0.6 cm was placed on the substrate of the photoelectrode, and then covered by the cathode, so that the two pores on the spacer were located on the diagonal line of the photoelectrode for injecting electrolyte therein. When all elements were set at the correct positions, the photoelectrode, spacer and cathode were fixed by clamps and heated to melt the spacer and adhere the upper and lower electrodes. The assembly was then cooled naturally and then the electrolyte was injected. After electrolyte injection, the pores of the spacer were sealed to avoid the evaporation of electrolyte, which may cause degeneration of the cell. When the cell assembly was completed, the cell was objected to the determination of cell efficiency.

The following examples are provided to elucidate the present invention, not to limit the scope of the present invention. Those skilled in the art will recognize and understand them without further explanation. All the references are hereby incorporated by reference in its entirety herein.

### Examples

### Example 1

### Analysis of Photoanode with TiO₂ Deposited Substrate

### I. Morphology Analysis of the TiO₂ Deposited Substrate

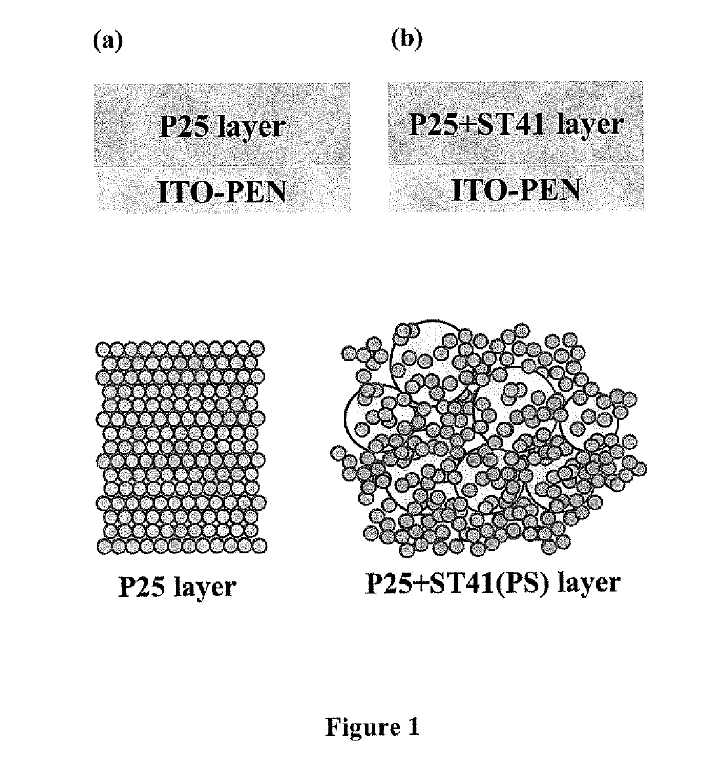

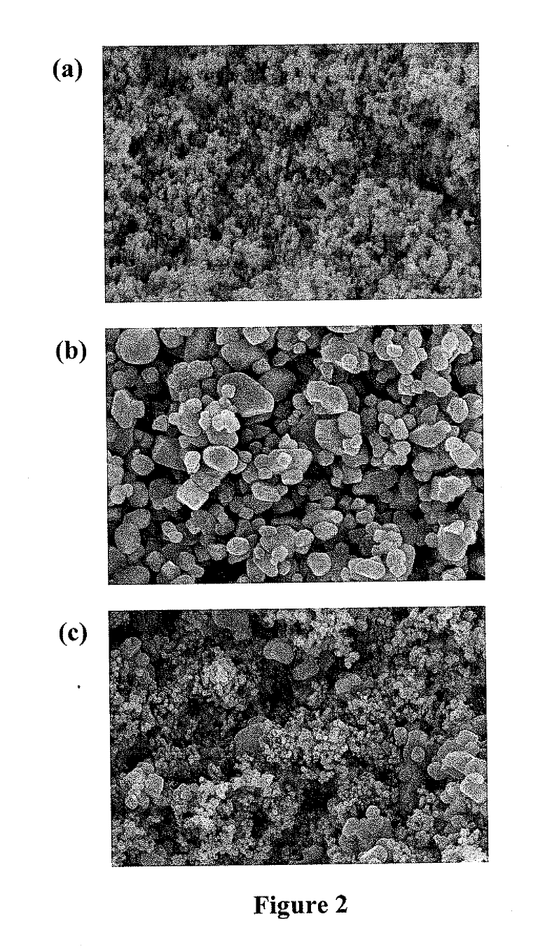

The morphology of electrophoretically deposited TiO₂ was examined after heat treatment and mechanical compression by scanning electron microscopy (SEM) (JEOL 1600). FIG. 1 shows the illustrative diagram of (a) P25 film and (b) PS (P25+ST41) film. FIG. 2 shows the SEM images of (a) P25, (b) ST41 and (c) PS deposited on ITO-PEN substrates under constant 20 V/cm electric field for (a) 120 s, (b) 40 s and (c) 80 s.

In conventional DSC assembly, the TiO₂ film of photoanode might comprise a P25 layer and a ST41 layer, in which ST41 was used for fabricating a scattering layer of photoanode. This would increase the cost and preparation time of FDSCs. However, in the present invention, P25 and ST41 were mixed and deposited. It was found that the deposited P25 particles were well-connected (FIG. 2(a)). When the mixture of P25 and ST41 (PS) was used, both P25 and ST41 were simultaneously deposited on the substrate (FIG. 2(c)). In other words, the addition of ST41 did not affect the connection among P25 particles in the PS TiO₂ sample.

### II. Thickness Analysis of TiO₂ Films Deposited on Photoanode Under Different Electrophoresis Conditions

The thickness of TiO₂ film deposited on photoanode influences the quality of film, the dye loading and cell efficiency. In this study, the TiO₂ deposited photoanodes were adhered on 2 cm×2 cm glass plate after heat treatment and mechanical compression and measured by new alpha-step profilometer (KLA-Tencor, AS500). The EPD condition and the thickness of P25 and PS films are listed in Tables 1 and 2.

TABLE 1
Film thickness results of single EPD P25 film on ITO-PEN after
heat treatment and mechanical compression at room temperature

| | EPD electric field | EPD time | Film thickness |
|---|---|---|---|
| Sample | (V/cm) | (min) | (μm) |
| A | 5 | 2 | 1.3 |
| B | 5 | 4 | 2.3 |
| C | 10 | 2 | 3.6 |
| D | 10 | 4 | 5.0 |
| E | 15 | 2 | 6.1 |
| F | 15 | 4 | 11.8 |
| G | 20 | 2 | 8.0 |
| H | 20 | 4 | 14.7 |
| I | 25 | 2 | 12.7 |
| J1 | 25 | 4 | crack |
| J2 | 30 | 2 | crack |

TABLE 2
Film thickness results of single EPD PS film on ITO-PEN after
heat treatment and mechanical compression at room temperature

| | EPD electric field | EPD time | Film thickness |
|---|---|---|---|
| Sample | (V/cm) | (min) | (μm) |
| K | 5 | 2 | 5.4 |
| L | 5 | 4 | 10.5 |
| M | 10 | 2 | 6.0 |
| N | 10 | 4 | 14.3 |
| O | 15 | 2 | 8.5 |
| P | 15 | 4 | 17.1 |
| Q | 20 | 2 | 12.1 |
| R | 20 | 4 | 18.3 |
| S | 25 | 2 | 15.2 |
| T1 | 25 | 4 | crack |
| T2 | 30 | 2 | crack |

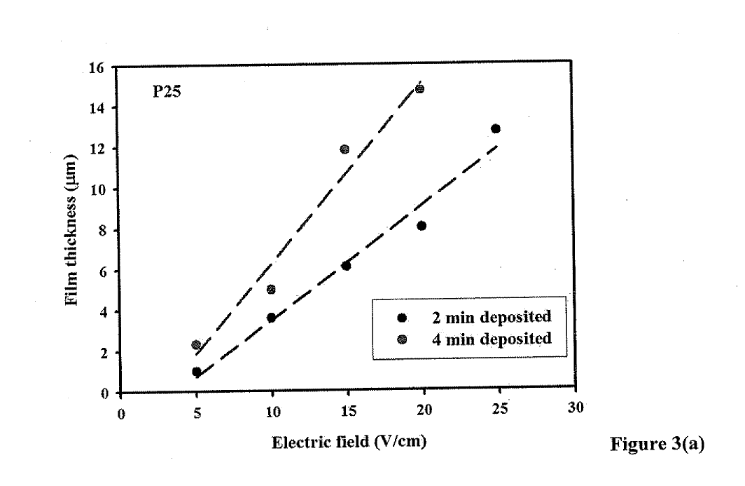

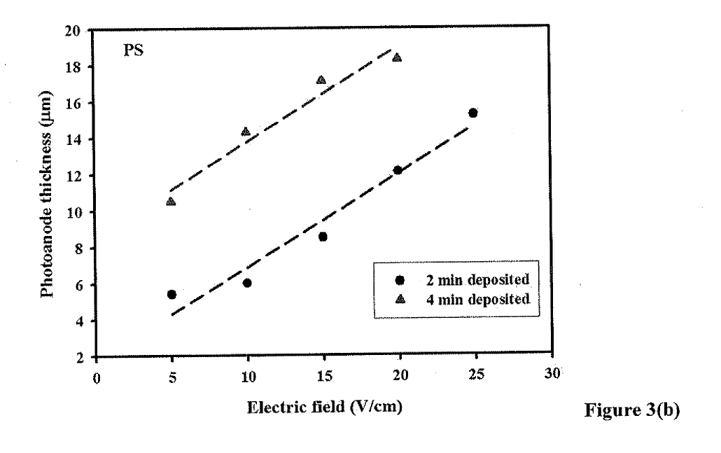

It was found that the TiO₂ film of photoanode was thicker when the EPD time was longer, and the thickness increased linearly with the EPD voltage, as shown in FIG. 3(a). In other words, it shows that the deposition yield is proportional to the electric field. However, when the electric field increased to 25 V/cm and the EPD time is 4 minutes, cracks appeared on P25 film. TiO₂ film comprises ethanol, and a thicker TiO₂ film comprised more ethanol; therefore, when the deposited TiO₂ film was dried, the solvent evaporation resulted in contraction of TiO₂ film and the cracks formed. These cracked films would depart from the ITO-PEN substrate after compression. The PS TiO₂ film had similar trends, but the thickness of the PS films is generally greater than P25 films, as shown in FIG. 3(b).

### III. BET Surface Area Analysis of TiO₂ Films Deposited on Photoanode Under Different Electrophoresis Conditions

The deposited TiO₂ films were independently scraped out as powder and the collected powder was subjected to heat treatment at 140° C. and analyzed by using Brunauer-Emmett-Teller (BET) method for determining the surface area, pore size and volume and porosity. These data of the collected P25 and PS powders after EPD are listed in Tables 3 and 4, respectively.

TABLE 3
BET related data of various P25 powders collected after EPD

| | Specific surface | Pore size | Pore volume | Porosity |
|---|---|---|---|---|
| Sample | area (m²/g) | (nm) | (cm³/g) | (%) |
| Raw P25 powder | 41 | 15 | 0.16 | 38 |
| A | 30 | 24 | 0.20 | 37 |
| B | 30 | 23 | 0.21 | 40 |
| C | 31 | 29 | 0.22 | 46 |
| D | 46 | 28 | 0.36 | 58 |
| E | 45 | 19 | 0.21 | 45 |
| F | 41 | 19 | 0.23 | 47 |
| G | 41 | 24 | 0.26 | 50 |
| H | 42 | 22 | 0.24 | 48 |
| I | 43 | 24 | 0.28 | 52 |

TABLE 4
BET related data of various PS powders collected after EPD

| | Specific surface | Pore size | Pore volume | Porosity |
|---|---|---|---|---|
| Sample | area (m²/g) | (nm) | (cm³/g) | (%) |
| Raw PS powder | 34 | 13 | 0.12 | 34 |
| K | 28 | 23 | 0.18 | 41 |
| L | 29 | 24 | 0.17 | 40 |
| M | 42 | 22 | 0.23 | 47 |
| N | 43 | 16 | 0.16 | 38 |
| O | 31 | 16 | 0.12 | 32 |
| P | 32 | 25 | 0.19 | 43 |
| Q | 31 | 28 | 0.20 | 44 |
| R | 31 | 33 | 0.26 | 50 |
| S | 31 | 23 | 0.19 | 43 |

It was known that surface area of TiO₂ affected dye loading. From the data of Table 3, it was found that the P25 powder collected after EPD generally had a higher surface area, pore size, pore volume and porosity than the raw P25 powder. The addition of charge solution made these TiO₂ particles charged and highly dispersed in the electrophoretic suspension, so the charged TiO₂ particles were hardly aggregated and their surface area increased. When the charged TiO₂ particles were deposited and stacked on the substrate, the stack of TiO₂ particles was not compact because of the repulsion between the charges on the TiO₂ particles, thereby resulting in great pore size and volume. PS powder has similar result, as shown in Table 4.

### IV. Dye Loading Analysis of TiO₂ Films Deposited on Photoanode Under Different Electrophoresis Conditions

The dye-loaded photoelectrodes were soaked in an alkali solution (such like 0.1M NaOH in ethanol) for about 1 hour to deabsorb the dye, and the resulted solutions were objected to analysis by UV-Vis spectrometer for calculating the dye loading. The results of P25 and PS are shown in Tables 5 and 6, respectively.

TABLE 5
The dye loading and cell efficiency of various P25 FDSCs

| | Dye loading | Dye loading per volume |
|---|---|---|
| Sample | (×10⁻⁷ mole/cm²) | (×10⁻³ mole/cm³) |
| A | 0.13 | 0.13 |
| B | 0.22 | 0.10 |
| C | 0.34 | 0.09 |
| D | 0.83 | 0.17 |
| E | 0.89 | 0.16 |
| F | 1.42 | 0.12 |
| G | 1.00 | 0.13 |
| H | 1.80 | 0.12 |
| I | 1.22 | 0.10 |

TABLE 6
The dye loading and cell efficiency of various PS FDSCs

| | Dye loading | Dye loading per volume |
|---|---|---|
| Sample | (×10⁻⁷ mole/cm²) | (×10⁻³ mole/cm³) |
| K | 0.21 | 0.04 |
| L | 0.33 | 0.03 |
| M | 0.37 | 0.06 |
| N | 0.55 | 0.04 |
| O | 0.62 | 0.07 |
| P | 1.11 | 0.06 |
| Q | 0.78 | 0.06 |
| R | 2.10 | 0.11 |
| S | 1.11 | 0.07 |

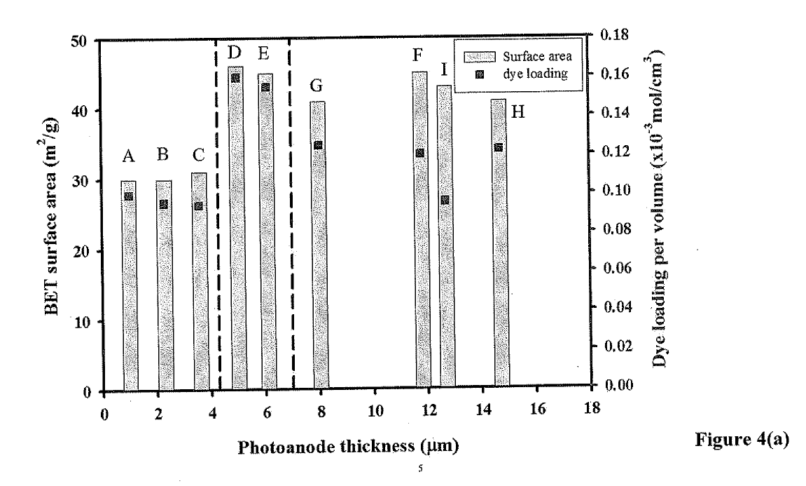

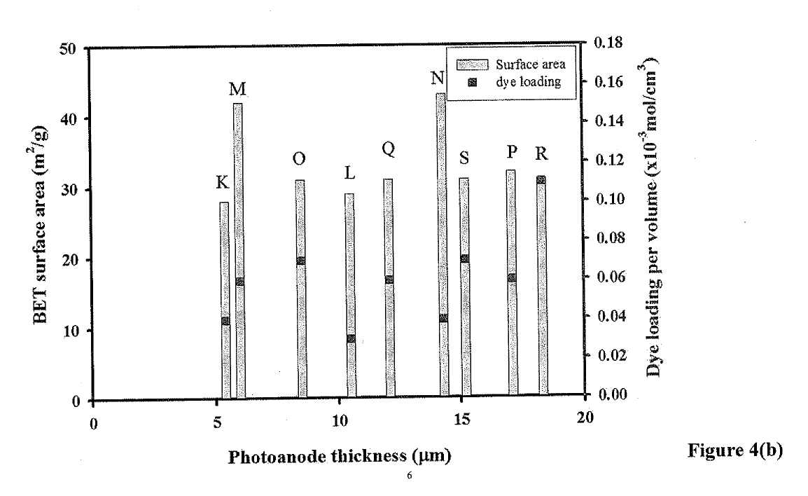

The relationship between the TiO₂ film thickness, surface area and dye loading per volume of P25 and PS TiO₂ films is shown in FIGS. 4(a) and 4(b), respectively. Generally speaking, the dye loading generally increases with the thickness of P25 TiO₂ film, but a closer examination including BET surface area and the dye loading per volume reveals further information. In FIG. 4(a), two vertical dashed lines divide the plot into three different regions. The dye loading per volume of the samples of the left middle regions increases and decreases with BET surface area; and the dye loading per volume of these samples is close to their BET surface area, which means, the dye is absorbed by TiO₂ completely. In the right region, however, the relation between the thickness, dye loading and the BET surface area is different: photoanodes F, G, H and I have a greater thickness of TiO₂ film, but their dye loading per volume are lower than the photoanodes of middle region. It is deduced that when the thickness of P25 TiO₂ film is over a special value, such as 6.1 μm, the dye does not go to the bottom of TiO₂ film and cannot be absorbed completely. As shown in FIG. 4(b), the surface area and dye loading per volume of PS TiO₂ films are generally lower than P25 TiO₂ films, which are resulted from the addition of ST41.

### Example 2

### Cell Efficiency Measurement of FDSCs with TiO₂ Films Deposited on Photoanode Under Different Electrophoresis Conditions

The flexible dye-sensitized solar cells comprising a photoanode with an electrophoretically deposited P25 or PS TiO₂ film were manufactured as foresaid. The cell efficiency (η) of the flexible dye-sensitized solar cells comprising P25 or PS TiO₂ film was measured by the standard method for measuring flexible dye-sensitized solar cell efficiency, in which solar simulator was used with parameter set at AM 1.5 G (=100 mW/cm²) to mimic the cell expression under true sun light. In addition, a power supply was used to provide an applied voltage to the dye-sensitized solar cell of the present invention in order to detect the resulted photocurrent. The applied voltage was changed to mimic the expression of cell under load, thereby calculating the short circuit current density (J_{sc}) and cell efficiency (η) of FDSCs comprising P25 or PS photoanode. The film thickness, dye loading and cell efficiency of P25 and PS cells are listed in Tables 7 and 8, respectively.

TABLE 7
Film thickness, dye loading, short circuit current density
and cell efficiency of various FDSCs with P25 photoanode

| | Film thickness | Dye loading | J_{sc} | η |
|---|---|---|---|---|
| Sample | (μm) | (×10⁻⁷ mole/cm²) | (mA/cm²) | (%) |
| A | 1.3 | 0.13 | 3.25 | 1.54 |
| B | 2.3 | 0.22 | 3.88 | 1.88 |
| C | 3.6 | 0.34 | 4.17 | 2.00 |
| D | 5.0 | 0.83 | 6.32 | 2.99 |
| E | 6.1 | 0.89 | 5.72 | 2.52 |
| F | 11.8 | 1.42 | 8.31 | 3.71 |
| G | 8.0 | 1.00 | 6.27 | 2.70 |
| H | 14.7 | 1.80 | 9.88 | 4.34 |
| I | 12.7 | 1.22 | 9.10 | 3.88 |

TABLE 8
Film thickness, dye loading, short circuit current density
and cell efficiency of various FDSCs with PS photoanode

| | Film thickness | Dye loading | J_{sc} | η |
|---|---|---|---|---|
| Sample | (μm) | (×10⁻⁷ mole/cm²) | (mA/cm²) | (%) |
| K | 5.4 | 0.21 | 4.38 | 2.00 |
| L | 10.5 | 0.33 | 5.86 | 2.68 |
| M | 6.0 | 0.37 | 5.58 | 2.50 |
| N | 14.3 | 0.55 | 6.54 | 2.94 |
| O | 8.5 | 0.62 | 6.95 | 3.30 |
| P | 17.1 | 1.11 | 8.88 | 3.76 |
| Q | 12.1 | 0.78 | 11.27 | 4.57 |
| R | 18.3 | 2.10 | 9.78 | 3.97 |
| S | 15.2 | 1.11 | 9.48 | 3.90 |

The TiO₂ film thickness, dye loading and short circuit current density of P25 FDSCs had positive linear relationship. Cell H had the greatest thickness and dye loading, produced more electrons attributing to the value of short circuit current density, and had the greatest cell efficiency (4.34%). From Table 7, it is clear that when the thickness of P25 film increases, the cell efficiency of the all-plastic FDSCs of the present invention increases.

In PS FDSCs, however, the relationship of TiO₂ film thickness, dye loading and cell efficiency was different from P25 FDSCs. ST41 had a greater particle size and moved slowly in the electrophoresis, so the higher electric field resulted in more ST41 particles attached the substrate. ST41 particles also served as scattering centers in PS photoanodes. Therefore, the relationship between TiO₂ film thickness and dye loading of PS FDSCs is irregular.

Although photoanodes in the right region (see FIG. 4(b)) have a lower dye loading per volume, but they have a greater TiO₂ film thickness. For this reason, they have a greater total dye loading. Increased dye loading generates more photo current to promote cell efficiency. Therefore, P25 and PS films having similar thickness were further selected and analyzed, for example, P25 Cell G (8.0 μm) and PS Cell O (8.5 μm), and P25 Cell I (12.7 μm) and PS Cell Q (12.1 μm).

Since the addition of ST41 reduced the specific surface area, the dye loading reduces by 38% from P25 Cell G to PS Cell 0, and reduced by 36% from P25 Cell I to PS Cell Q. However, the J_{sc} and the cell efficiency of these PS cells (0, Q) were better than P25 cells (G, I). Comparing Cells 0 to G, an 11% increase in the J_{sc} was obtained, leading to a 22% increase in cell efficiency. Comparing Cells Q to I, a 24% increase in the J_{sc} was obtained, leading to an 18% increase in cell efficiency. The lesser improvement in the cell efficiency for Cell Q is due to its lower FF than that of Cell I (data not shown). The enhancement in J_{sc} can be understood by considering the fact that ST41 particles serve as scattering centers and enhance light harvesting.

### Example 3

### Light Absorbance, Electron Diffusion Time and Electron Lifetime of FDSCs with TiO₂ Films Deposited on Photoanode Under Different Electrophoresis Conditions

Light absorbance of the photoanodes of the present invention was measured by an UV/Vis spectrophotometer (PerkinElmer, LAMBDA™ 950) in the wavelength range between 400 nm to 800 nm with 1 nm data interval. The results are shown in Table 9.

In addition, IMPS/VS (intensity modulated photocurrent/photovoltage spectroscopy) (ZAHNER, IM6e) was used for measuring internal electron transfer and internal behavior of electrons in DSCs. Under constant voltage mode and constant current mode, when light frequency was changing, a series of delayed photocurrent and photovoltage responses were recorded and calculated to give electron diffusion time (τ_{d}) and electron lifetime (τₙ), respectively. Since the photoanodes have different TiO₂ film thicknesses, the electron diffusion time is divided by thickness to determine the electron diffusion time per unit length (τ_{d}/t). The results are shown in Table 9.

TABLE 9
The total light absorbance, electron diffusion time
and electron lifetime of specific P25 and PS FDSCs

| | Total | τ_{d} | τ_{d}/t | τₙ |
|---|---|---|---|---|
| Sample | absorbance | (ms) | (ms/μm) | (ms) |
| F | 205 | 12.40 | 1.05 | 27.11 |
| G | 192 | 8.08 | 1.01 | 16.79 |
| H | 207 | 10.73 | 0.73 | 32.05 |
| I | 207 | 9.30 | 0.73 | 23.03 |
| O | 75 | 7.05 | 0.83 | 16.97 |
| Q | 149 | 2.58 | 0.21 | 23.03 |

Regarding with Cells F, G, H and I, the former two have similar values of τ_{d}/t and so do the latter two. In other words, τ_{d}/t of Cells H and I are faster than Cells F and G. As we know, a photoanode having a better light absorbance generates more photoelectrons. As the surface states in these P25 photoanodes are the same, more traps can be occupied in a photoanode having more photoelectrons. This leads to a faster diffusion time per unit length.

As for the electron lifetime, it is generally proportional to the photoanode thickness. This can be explained by considering the electron density, and the recombination of the redox couple and photoelectron. After the incident light enters into a cell from the current collector side, the photon flux reduces with the light path, i.e., the photoanode thickness, due to light absorption. Since a higher photon flux generates more photoelectrons, the electron density is always higher near the current collector. For a thicker photoanode, it is more difficult for a redox couple in the electrolyte to diffuse near to the current collector; therefore, less recombination occurs near the current collector. On the other hand, although the electrolyte side has redox couple, but the electron density is low, which means less recombination occurs. As a result, a photoanode with a thicker TiO₂ film has a longer electron lifetime.

### Example 4

### IPCE of FDSCs with TiO₂ Films Deposited on Photoanode Under Different Electrophoresis Conditions

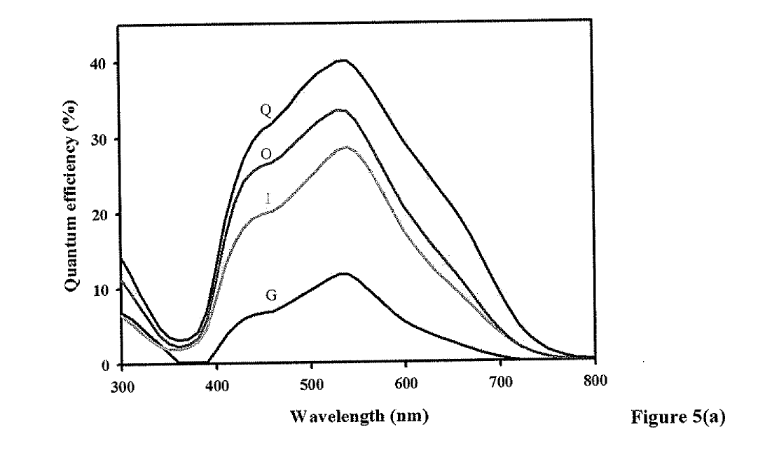

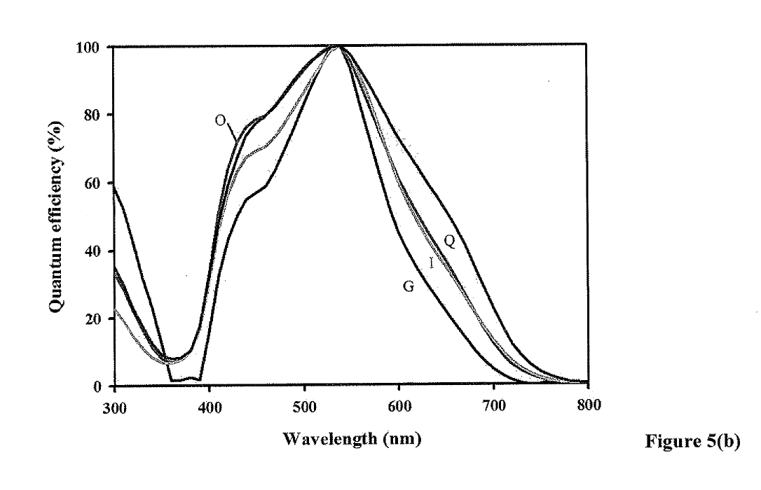

Quantum Efficiency Measurement System, Oriel IQE-200 was used to evaluate the incident photon-to-electron conversion efficiency (IPCE) of specific cells of the present invention. The IPCE spectra are shown in FIG. 5(a). In order to remove the difference of dye loading, the highest peak is normalized by identifying the highest peak as 100%, and the other peaks are correspondingly adjusted. Normalized IPCE spectra are shown in FIG. 5(b).

IPCE is also known as quantum efficiency, which is generally directs to external quantum efficiency, i.e. electrical energy obtained from the incident light. The energy loss caused by reflection of incident light is not considered.

As discussed above, ST41 particles serve as scattering centers and enhance light harvesting, and this leads to improved IPCE. The IPCEs of PS Cells O and Q show obvious light scattering due to the addition of ST41 powders into P25 powders, as shown in FIGS. 5(a) and 5(b).

Due to the better IPCE performance or higher J_{sc}, there are more electrons in photoanodes O and Q. Also, the ST-41 powders are pure anatase TiO₂, giving less resistance for electron transport than the rutile-containing P-25 powders. As a result, the electron diffusion times of photoanodes O and Q are faster, as shown in Table 9. Meanwhile, the electron lifetimes appear to be the same, regardless of the addition of ST-41 powders.

Regarding with Cells I and Q, Cell I has a longer lifetime, which is resulted from a lower current density and a lower recombination rate. However, the pore volume of Photoanode G (0.26 cm³/g) is higher than that of photoanode O (0.12 cm³/g). This indicates that the electrolyte penetrates into the pores more easily in Cell G than in Cell O. Thus the electrons in Photoanode I have a higher probability of recombining with the holes in the electrolyte, leading to a reduced electron lifetime. For the same reason, cells I and Q exhibit similar electron lifetimes.

In summary, the present invention provides a binder-free EPD process for preparing a photoanode with a deposited TiO₂ film by using PS (P25+ST41) TiO₂ powders, and a flexible dye-sensitized solar cell comprising the photoanode with a deposited TiO₂ film. The EPD process of the present invention allows controlling multiple factors key to cell efficiency, such as the thickness, porosity and dye loading of the TiO₂ film deposited on the photoanode. ST41 particles serve as light scattering centers, and PS FDSCs of the present invention exhibit enhanced cell efficiency than the P25 FDSCs, and the enhancement reaches up to 22%.

1. A binder-free process for preparing a photoanode of flexible dye-sensitized solar cell, comprising:
(a) preparing a TiO₂ suspension fluid comprising TiO₂, acetylacetone and anhydrous ethanol, wherein said TiO₂ is selected from P25, ST41 or combinations thereof;
(b) preparing a charge solution comprising iodine, ketone and deionized water;
(c) mixing said TiO₂ suspension fluid and said charge solution to obtain an electrophoresis suspension;
(d) soaking a substrate and a cathode into the electrophoresis suspension and proceeding electrophoresis to obtain an TiO₂ deposited substrate at a voltage of 25V or less, wherein said substrate and said cathode are plastic flexible;
(e) heating the TiO₂ deposited substrate; and
(d) compressing the heated TiO₂ substrate to obtain the photoanode at 20 kg/cm²˜50 kg/cm².

2. (canceled)

3. The process according to claim 1, wherein said TiO₂ is selected from combinations of P25 and ST41.

4. The process according to claim 3, wherein said P25 and ST41 are combined with a ratio of 0.5˜9:1.

5. The process according to claim 1, wherein said TiO₂, acetylacetone and anhydrous ethanol are combined with a ratio of 3 g˜4 g:1.2 mL˜2 mL:1 L˜1.2 L.

6. The process according to claim 1, wherein said iodine, ketone and deionized water of step (b) are combined with a ratio of 0.067 g˜0.075 g:10 mL˜15 mL:5 mL˜10 mL.

7. The process according to claim 1, wherein said substrate is a flexible substrate.

8. The process according to claim 7, wherein said flexible substrate is selected from an ITO-PEN, ITO-PET, titanium or stainless steel substrate.

9. The process according to claim 1, wherein said substrate and said cathode are arranged with a distance of 0.5 cm˜1.2 cm in step (d).

10. The process according to claim 1, said deposited TiO₂ substrate is heated at 100-140° C. in step (e).

11. (canceled)
